(19) United States
(12) Patent Application Publication
(10) Pub. No.: US 2015/0035575 A1
(43) Pub. Date: Feb. 5, 2015

(54) DATA OUTPUT CIRCUITS

(71) Applicant: SK hynix Inc., Icheon-si (KR)

(72) Inventor: Jae Woong YUN, Seoul (KR)

(73) Assignee: SK hynix Inc., Icheon-si (KR)

(21) Appl. No.: 14/105,399

(22) Filed: Dec. 13, 2013

(30) Foreign Application Priority Data
Jul. 30, 2013 (KR) 10-2013-0089980

(51) Int. Cl. H03K 3/017

(52) U.S. Cl. CPC H03K 3/017
USPC 327/218

(57) ABSTRACT

Data output circuits are provided. The data output circuit includes a latch control signal generator and a data output portion. The latch control signal generator generates an input pulse signal and a latch control signal i, and the latch control signal includes a pulse whose width is controlled to have a predetermined time period. The data output portion latches a data loaded on an input/output (I/O) line during a pulse width period of the latch control signal to generate a latch data. Moreover, the data output portion buffers the latch data according to an output control signal generated from a read command signal to output the buffered latch data as an output data.

### CROSS-REFERENCE TO RELATED APPLICATION

The present application claims priority under 35 U.S.C 119(a) to Korean Application No. 10-2013-0089980, filed on Jul. 30, 2013, in the Korean Intellectual Property Office, which is incorporated herein by reference in its entirety as set forth in full.

### BACKGROUND

1. Technical Field

Embodiments of the present disclosure relate to semiconductor integrated circuits and, more particularly, to data output circuits including pipe latch circuits.

2. Related Art

Semiconductor devices have been continuously scaled down with the improvement of operation speed. At first, the semiconductor devices have been designed such that a plurality of data of each semiconductor device have been outputted in synchronization with every rising edge of the external clock signal. Recently, the semiconductor devices have been designed such that a plurality of data of each semiconductor device have been outputted in synchronization with every rising edge as well as every falling edge of the external clock signal to more improve the operation speed thereof.

Meanwhile, the semiconductor device may employ a pipe latch circuit that successively outputs a plurality of data in synchronization with an external clock to efficiently process the plurality of data. The pipe latch circuit may execute an operation that latches a plurality of data stored in memory cells of the semiconductor device and may also execute an operation that sequentially receives the plurality of data according to address signals to output the plurality of data. The operation latching the plurality of data may be referred to as a pre-fetch operation. For example, a two-bit pre-fetch operation means an operation that latches two data at a time according to a read command signal and a four-bit pre-fetch operation means an operation that latches four data at a time according to a read command signal.

As such, the semiconductor device may efficiently process a plurality data using a pipe latch circuit.

### SUMMARY

Various embodiments are directed to data output circuits.

According to various embodiments, a data output circuit includes a latch control signal generator and a data output portion. The latch control signal generator generates an input pulse signal and a latch control signal, and the latch control signal includes a pulse whose width is controlled to have a predetermined time period. The data output portion latches a data loaded on an input/output (I/O) line during a pulse width period of the latch control signal to generate a latch data. Moreover, the data output portion buffers the latch data according to an output control signal generated from a read command signal to output the buffered latch data as an output data.

According to various embodiments, a data output circuit includes a latch control signal generator and a latch unit. The latch control signal generator generates a first input pulse signal and a first latch control signal in response to a first pulse of a read command signal. In addition, the latch control signal generator generates a second input pulse signal and a second latch control signal in response to a second pulse of the read command signal. The latch unit latches first and second data loaded on first and second I/O lines during a pulse width period of the first latch control signal to generate first and second latch data. Moreover, the latch unit latches third and fourth data loaded on third and fourth I/O lines during a pulse width period of the second latch control signal to generate third and fourth latch data. The first latch control signal is enabled from when the first pulse of the read command signal is inputted till when a third pulse of the read command signal is inputted, and the second latch control signal is enabled from when the second pulse of the read command signal is inputted till when a fourth pulse of the read command signal is inputted.

According to various embodiments, a data output circuit includes a latch control signal generator, an output control signal generator and a data output portion. The latch control signal generator generates an input pulse signal, an output pulse signal and a latch control signal. The latch control signal includes a pulse whose width is controlled to have a predetermined time period. The output control signal generator generates first and second output control signals enabled when the output pulse signal is inputted. The data output portion latches first and second data loaded on first and second input/output (I/O) lines during a pulse width period of the latch control signal to generate first and second latch data. Furthermore, the data output portion buffers the first and second latch data according to the first and second output control signals to output the buffered first and second latch data as a first output data and a second output data.

According to an embodiment, a data output circuit includes: a latch control signal generator configured to generate one or more input pulse signals and one or more latch control signals having a predetermined pulse width; and a data output portion configured to latch data loaded onto a one or more input/output lines to generate a plurality of latch data and buffer the plurality of latch data to output a plurality of output data.

### BRIEF DESCRIPTION OF THE DRAWINGS

Embodiments of the inventive concept will become more apparent in view of the attached drawings and accompanying detailed description, in which:

FIG. 1 is a block diagram illustrating a data output circuit according to an embodiment of the present invention;

FIG. 2 is a circuit diagram illustrating a pulse width controller included in the data output circuit of FIG. 1;

FIG. 3 is a circuit diagram illustrating a selection signal generator included in the data output circuit of FIG. 1;

FIG. 4 is a circuit diagram illustrating a latch unit included in the data output circuit of FIG. 1;

FIG. 5 is a circuit diagram illustrating a buffer unit included in the data output circuit of FIG. 1;

FIG. 6 is a timing diagram illustrating an operation of a data output circuit according to an embodiment of the present invention;

FIG. 7 is a circuit diagram illustrating another example of a latch unit included in the data output circuit of FIG. 1; and

FIG. 8 is a timing diagram illustrating an operation of a data output circuit according to an embodiment of the present invention.

### DETAILED DESCRIPTION

Various embodiments of the present invention will be described hereinafter with reference to the accompanying drawings. However, the embodiments described herein are for illustrative purposes only and are not intended to limit the scope of the present invention.

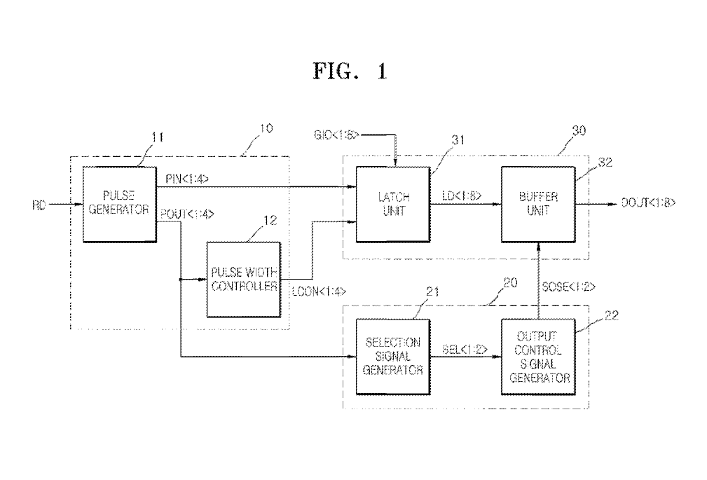

As illustrated in FIG. 1, a data output circuit according to an embodiment of the present invention may include a latch control signal generator 10, an output control signal generator 20, and a data output portion 30.

The latch control signal generator 10 may include a pulse generator 11 and a pulse width controller 12. The pulse generator 11 may sequentially generate first to fourth input pulse signals PIN<1:4> and first to fourth output pulse signals POUT<1:4> in synchronization with pulses of a read command signal RD, and the pulse width controller 12 may control pulse widths of the first to fourth output pulse signals POUT<1:4> to sequentially generate first to fourth latch control signals LCON<1:4> having a predetermined pulse width. That is, the latch control signal generator 10 may receive the pulses of the read command signal RD to sequentially generate the first to fourth input pulse signals PIN<1:4> and to sequentially generate the first to fourth latch control signals LCON<1:4> having the predetermined pulse width.

The output control signal generator 20 may include a selection signal generator 21 and an output control signal generator 22. The selection signal generator 21 may generate a first selection signal SEL<1> enabled when the first or third output pulse signal POUT<1> or POUT<3> is inputted; and may generate a second selection signal SEL<2> enabled when the second or fourth output pulse signal POUT<2> or POUT<4> is inputted. The output control signal generator 22 may sequentially generate a first output control signal SOSE<1> and a second output control signal SOSE<2> when the first selection signal SEL<1> or the second selection signal SEL<2> is inputted. That is, the output control signal generator 20 may generate the first and second output control signals SOSE<1> and SOSE<2> sequentially enabled when any one of the first to fourth output pulse signals POUT<1:4> is inputted.

The data output portion 30 may include a latch unit 31 and a buffer unit 32. The latch unit 31 may receive data loaded on first to eighth input/output (I/O) lines GIO<1:8> according to the first to fourth input pulse signals PIN<1:4> and may latch in parallel the data loaded on the first to eighth I/O lines GIO<1:8> during pulse width periods of the first to fourth latch control signals LCON<1:4> to generate first to eighth latch data LD<1:8>. The buffer unit 32 may buffer the first to eighth latch data LD<1:8>, which are latched in parallel, in response to the first and second output control signals SOSE<1> and SOSE<2> to output in series first to eighth output data DOUT<1:8>. That is, the data output portion 30 may receive the data loaded on the first to eighth input/output (I/O) lines GIO<1:8> according to the first to fourth input pulse signals PIN<1:4>; may latch in parallel the data loaded on the first to eighth I/O lines GIO<1:8> during the pulse width periods of the first to fourth latch control signals LCON<1:4> to generate the first to eighth latch data LD<1:8>; and may buffer the first to eighth latch data LD<1:8> in response to the first and second output control signals SOSE<1> and SOSE<2> to output in series the first to eighth output data DOUT<1:8>.

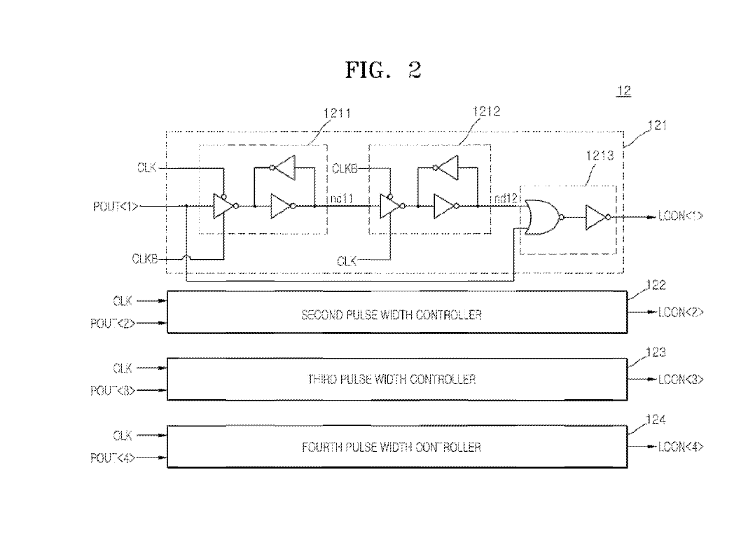

A configuration of the pulse width controller 12 will be described more fully hereinafter with reference to FIG. 2.

Referring to FIG. 2, the pulse width controller 12 may include first to fourth pulse width controllers 121, 122, 123 and 124. The first pulse width controller 121 may include a first delay unit 1211 retarding the first output pulse signal POUT<1> by half a cycle of an external clock signal CLK to output the retarded first output pulse signal POUT<1> through a node ND11; a second delay unit 1212 retarding a signal of the node ND11 by half a cycle of an external clock signal CLK to output the retarded signal through a node ND12; and a logic unit 1213 executing a NOR operation of the first output pulse signal POUT<1> and a signal on the node ND12 to generate the first latch control signal LCON<1>. That is, the first pulse width controller 121 may generate the first latch control signal LCON<1> which is enabled at a point of time that the first output pulse signal POUT<1> is enabled in synchronization with a rising edge of the external clock signal CLK and which is disabled after one cycle of the external clock signal CLK from a point of time that the first output pulse signal POUT<1> is disabled. Each of the second, third and fourth pulse width controllers 122, 123 and 124 may have substantially the same configuration as the first pulse width controller 121 except I/O signals thereof. Thus, detailed descriptions of the second, third and fourth pulse width controllers 122, 123 and 124 will be omitted hereinafter. In FIG. 2, the external clock signal CLK may be supplied from an external device, and a complementary external clock signal CLKB may correspond to a signal that the external clock signal CLK is inverted.

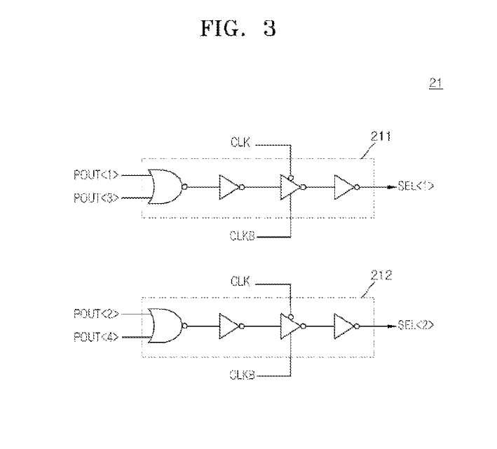

A configuration of the selection signal generator 21 will be described more fully hereinafter with reference to FIG. 3.

Referring to FIG. 3, the selection signal generator 21 may include a first selection signal generator 211 and a first selection signal generator 211 and a second selection signal generator 212.

The first selection signal generator 211 may generate the first selection signal SEL<1> enabled in synchronization with a falling edge of the external clock signal CLK when the first output pulse signal POUT<1> or the third output pulse signal POUT<3> is inputted. The second selection signal generator 212 may generate the second selection signal SEL<2> enabled in synchronization with a falling edge of the external clock signal CLK when the second output pulse signal POUT<2> or the fourth output pulse signal POUT<4> is inputted. That is, the selection signal generator 21 may generate the first selection signal SEL<1> having a logic “high” level in synchronization with a falling edge of the external clock signal CLK when the first output pulse signal POUT<1> or the third output pulse signal POUT<3> is inputted. Further, the selection signal generator 21 may generate the second selection signal SEL<2> having a logic “high” level in synchronization with a falling edge of the external clock signal CLK when the second output pulse signal POUT<2> or the fourth output pulse signal POUT<4> is inputted. FIG. 3 also illustrates the complementary external clock signal CLKB.

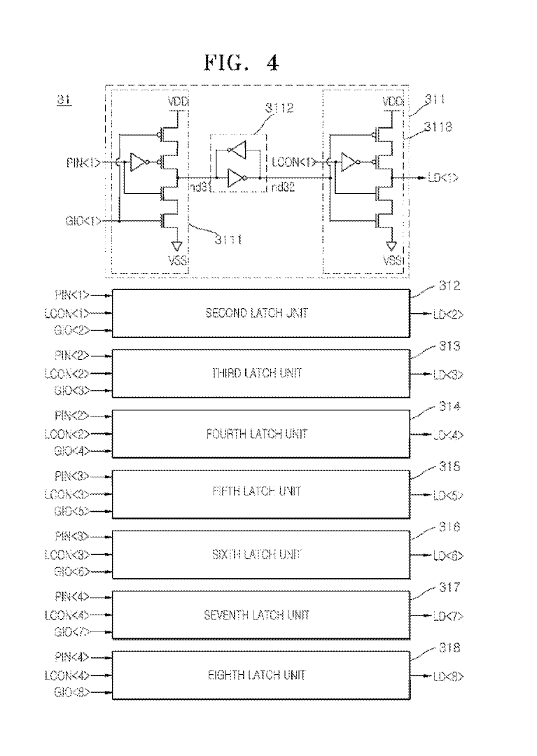

A configuration of the latch unit 31 will be described more fully hereinafter with reference to FIG. 4.

Referring to FIG. 4, the latch unit 31 may include first to eighth latch units 311, 312, 313, 314, 315, 316, 317 and 318.

The first latch unit 311 may include a first driver 3111 inversely buffering a data loaded on the first I/O line GIO<1> to output the inversely buffered data through a node ND31 when the first input pulse signal PIN<1> is inputted; a latch part 3112 latching and inversely buffering a signal on the node ND31 to output the latched and inversely buffered signal through a node ND32; and a second driver 3113 buffering a signal on the node ND32 during a pulse width period of the first latch control signal LCON<1> to generate the first latch data LD<1>. The second latch unit 312 may latch a signal on the second I/O line GIO<2> during a pulse width period of the first latch control signal LCON<1> to generate the second latch data LD<2> when the first input pulse signal PIN<1> is inputted. The third latch unit 313 may latch a signal on the third I/O line GIO<3> during a pulse width period of the second latch control signal LCON<2> to generate the third latch data LD<3> when the second input pulse signal PIN<2> is inputted. The fourth latch unit 314 may latch a signal on the fourth I/O line GIO<4> during a pulse width period of the second latch control signal LCON<2> to generate the fourth latch data LD<4> when the second input pulse signal PIN<2> is inputted. The fifth latch unit 315 may latch a signal on the fifth I/O line GIO<5> during a pulse width period of the third latch control signal LCON<3> to generate the fifth latch data LD<5> when the third input pulse signal PIN<3> is inputted. The sixth latch unit 316 may latch a signal on the sixth I/O line GIO<6> during a pulse width period of the third latch control signal LCON<3> to generate the sixth latch data LD<6> when the third input pulse signal PIN<3> is inputted. The seventh latch unit 317 may latch a signal on the seventh I/O line GIO<7> during a pulse width period of the fourth latch control signal LCON<4> to generate the seventh latch data LD<7> when the fourth input pulse signal PIN<4> is inputted. The eighth latch unit 318 may latch a signal on the eighth I/O line GIO<8> during a pulse width period of the fourth latch control signal LCON<4> to generate the eighth latch data LD<8> when the fourth input pulse signal PIN<4> is inputted. Each of the second to eighth latch units 312, 313, 314, 315, 316, 317 and 318 may have substantially the same configuration as the first latch unit 311 except I/O signals thereof. Thus, detailed descriptions of the second to eighth latch units 312, 313, 314, 315, 316, 317 and 318 will be omitted hereinafter. FIG. 4 also illustrates a voltage drain VDD and a voltage source VSS.

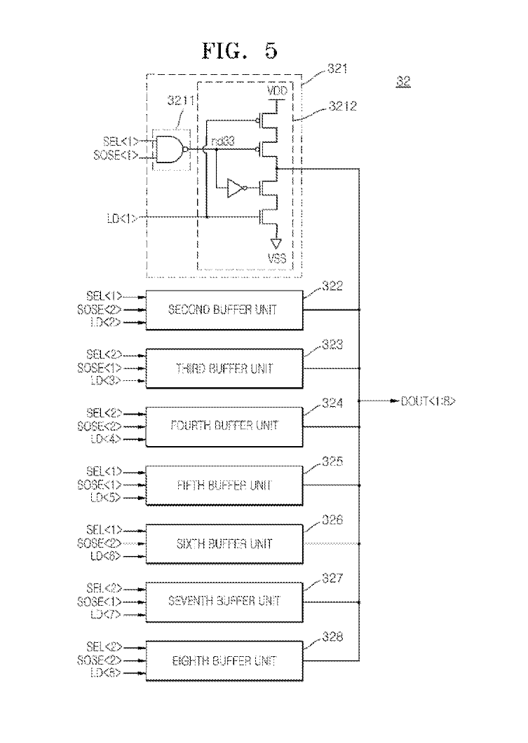

A configuration of the buffer unit 32 will be described more fully hereinafter with reference to FIG. 5.

Referring to FIG. 5, the buffer unit 32 may include first to eighth buffer units 321, 322, 323, 324, 325, 326, 327 and 328.

The first buffer unit 321 may include a logic element 3211 driving a node ND33 to have a logic “low” level when the first selection signal SEL<1> and the first output control signal SOSE<1> are enabled and; a buffer 3212 inversely buffering the first latch data LD<1> to generate the first output data DOUT<1> when the node ND33 is driven to have a logic “low” level. The second buffer unit 322 may inversely buffer the second latch data LD<2> to generate the second output data DOUT<2> when the first selection signal SEL<1> and the second output control signal SOSE<2> are enabled. The third buffer unit 323 may inversely buffer the third latch data LD<3> to generate the third output data DOUT<3> when the second selection signal SEL<2> and the first output control signal SOSE<1> are enabled. The fourth buffer unit 324 may inversely buffer the fourth latch data LD<4> to generate the fourth output data DOUT<4> when the second selection signal SEL<2> and the second output control signal SOSE<2> are enabled. The fifth buffer unit 325 may inversely buffer the fifth latch data LD<5> to generate the fifth output data DOUT<5> when the first selection signal SEL<1> and the first output control signal SOSE<1> are enabled. The sixth buffer unit 326 may inversely buffer the sixth latch data LD<6> to generate the sixth output data DOUT<6> when the first selection signal SEL<1> and the second output control signal SOSE<2> are enabled. The seventh buffer unit 327 may inversely buffer the seventh latch data LD<7> to generate the seventh output data DOUT<7> when the second selection signal SEL<2> and the first output control signal SOSE<1> are enabled. The eighth buffer unit 328 may inversely buffer the eighth latch data LD<8> to generate the eighth output data DOUT<8> when the second selection signal SEL<2> and the second output control signal SOSE<2> are enabled. Each of the second to eighth buffer units 322, 323, 324, 325, 326, 327 and 328 may have substantially the same configuration as the first buffer unit 321 except I/O signals thereof. Thus, detailed descriptions of the second to eighth buffer units 322, 323, 324, 325, 326, 327 and 328 will be omitted hereinafter. FIG. 5 also illustrates the voltage drain VDD and the voltage source VSS.

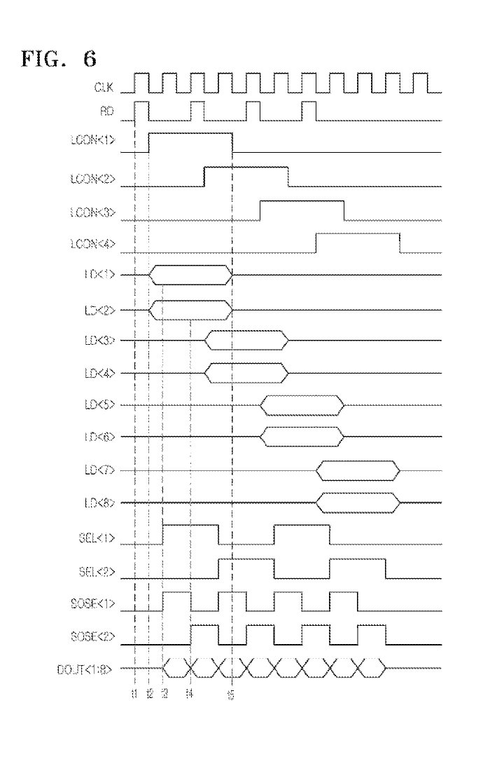

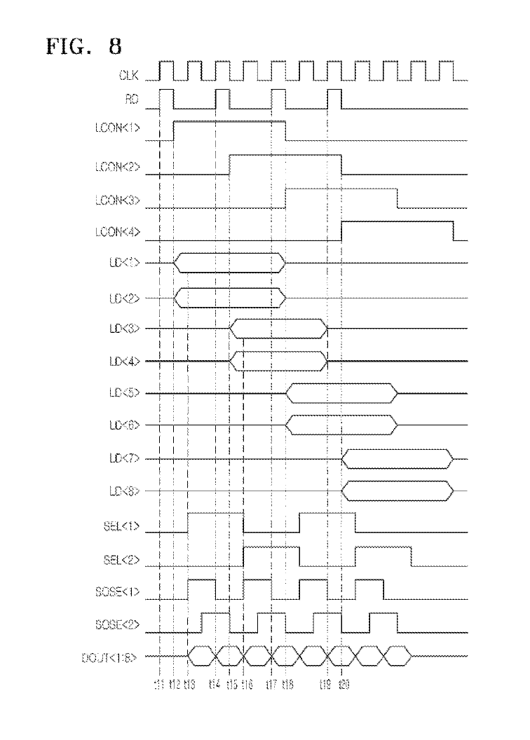

An operation of the data output circuit as set forth above will be described hereinafter with reference to FIGS. 1 and 6 and FIG. 8 in conjunction with an example that signals loaded on the first to eighth I/O lines GIO<1:8> are latched and outputted during a pulse width period of the first latch control signal LCON<1> generated by a first pulse of the read command signal RD.

At a point of time “T1”, the pulse generator 11 of the latch control signal generator 10 may receive a first pulse of the read command signal RD synchronized with the external clock signal CLK to generate the first input pulse signal PIN<1> having a logic “high” level and to generate the first output pulse signal POUT<1> having a logic “high” level.

Next, at a point of time “T2”, the pulse width controller 12 of the latch control signal generator 10 may receive the first output pulse signal POUT<1> having a logic “high” level to generate the first latch control signal LCON<1> having a logic “high” level. The latch unit 31 of the data output portion 30 may receive the first input pulse signal PIN<1> having a logic “high” level to latch the data loaded on the first and second I/O lines GIO<1> and GIO<2>; and may receive the first latch control signal LCON<1> having a logic “high” level to generate the first and second latch data LD<1> and LD<2>.

Subsequently, at a point of time “T3”, the selection signal generator 21 of the output control signal generator 20 may receive the first output pulse signal POUT<1> having a logic “high” level to generate the first selection signal SEL<1> having a logic “high” level. The output control signal generator 22 of the output control signal generator 20 may receive the first selection signal SEL<1> having a logic “high” level to generate the first output control signal SOSE<1> having a logic “high” level and the second output control signal SOSE<2> having a logic “low” level. The buffer unit 32 of the data output portion 30 may receive the first output control signal SOSE<1> having a logic “high” level to output the first latch data LD<1> latched at the point of time “T2” as the first output data DOUT<1>. That is, the data output portion 30 may receive the first output control signal SOSE<1> after a level of the first latch data LD<1> is stabilized, thereby stably outputting the first output data DOUT<1>.

Next, at a point of time “T4”, the output control signal generator 22 of the output control signal generator 20 may receive the first selection signal SEL<1> having a logic “high” level to generate the first output control signal SOSE<1> having a logic “low” level and to generate the second output control signal SOSE<2> having a logic “high” level. The buffer unit 32 of the data output portion 30 may receive the second output control signal SOSE<2> having a logic “high” level to output the second latch data LD<2> latched at the point of time “T2” as the second output data DOUT<2>. That is, the data output portion 30 may receive the second output control signal SOSE<2> after a level of the second latch data LD<2> is stabilized, thereby stably outputting the second output data DOUT<2>.

Next, at a point of time “T5”, the pulse width controller 12 of the latch control signal generator 10 may generate the first latch control signal LCON<1> having a logic “low” level after one cycle of the external clock signal CLK from a point of time that the first output pulse signal POUT<1> is generated to have a logic “low” level. The latch unit 31 of the data output portion 30 may receive the first input pulse signal PIN<1> having a logic “low” level not to generate the first and second latch data LD<1> and LD<2>.

Operations of the data output circuit for generating the third to eighth output data DOUT<3:8> may be substantially the same as the operation of the data output circuit for generating the first and second output data DOUT<1:2>. Thus, the operations of the data output circuit for generating the third to eighth output data DOUT<3:8> will be omitted hereinafter.

As described above, a data output circuit according to an embodiment of the present invention may increase a pulse width of a latch control signal generated by a read command signal to increase a latch period of data. Furthermore, the data output circuit may generate output control signals during a pulse width period of the latch control signal to output latched data as output data after levels of the latched data are stabilized. Thus, the output data may be stably outputted.

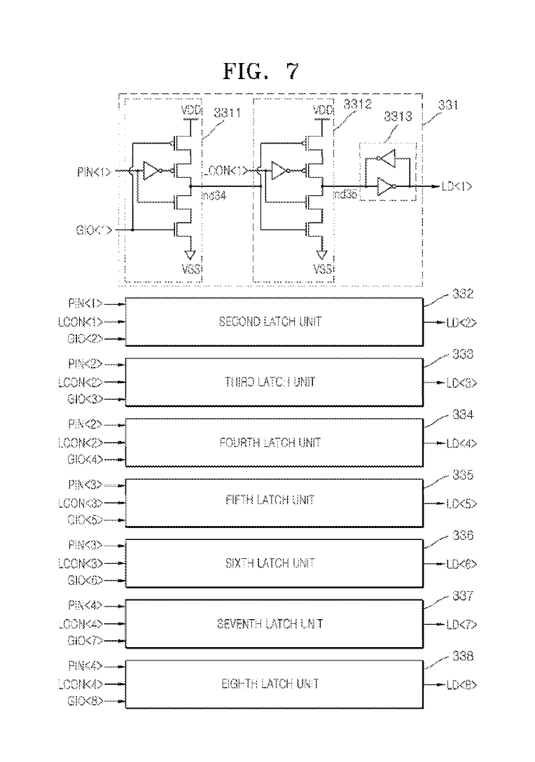

Referring to FIG. 7, a latch unit 31 of a data output circuit according to an embodiment of the present invention may be configured to include first to eighth latch units 331, 332, 333, 334, 335, 336, 337 and 338. The first latch unit 331 may include a first driver 3311 inversely buffering a data loaded on the first I/O line GIO<1> to output the inversely buffered data through a node ND34 when the first input pulse signal PIN<1> is inputted; a second driver 3312 inversely buffering a signal on the node ND34 to output the inversely buffered data through a node ND35 when the first latch control signal LCON<1> is inputted; and a latch part 3313 latching and inversely buffering a signal on the node ND35 to generate the first latch data LD<1>. The second latch unit 332 may latch a signal on the second I/O line GIO<2> to generate the second latch data LD<2> when the first input pulse signal PIN<1> and the first latch control signal LCON<1> are inputted. In various embodiments, the first and second latch units 331 and 332 may be designed such that latching operations for generating the first and second latch data LD<1:2> terminate until the third latch control signal LCON<3> is inputted. Alternatively, the first and second latch units 331 and 332 may be designed such that latching operations for generating the first and second latch data LD<1:2> terminate after the third latch control signal LCON<3> is inputted. The third latch unit 333 may latch a signal on the third I/O line GIO<3> to generate the third latch data LD<3> when the second input pulse signal PIN<2> and the second latch control signal LCON<2> are inputted. The fourth latch unit 334 may latch a signal on the fourth I/O line GIO<4> to generate the fourth latch data LD<4> when the second input pulse signal PIN<2> and the second latch control signal LCON<2> are inputted. The fifth latch unit 335 may latch a signal on the fifth I/O line GIO<5> to generate the fifth latch data LD<5> when the third input pulse signal PIN<3> and the third latch control signal LCON<3> are inputted. The sixth latch unit 336 may latch a signal on the sixth I/O line GIO<6> to generate the sixth latch data LD<6> when the third input pulse signal PIN<3> and the third latch control signal LCON<3> are inputted. The seventh latch unit 337 may latch a signal on the seventh I/O line GIO<7> to generate the seventh latch data LD<7> when the fourth input pulse signal PIN<4> and the fourth latch control signal LCON<4> are inputted. The eighth latch unit 338 may latch a signal on the eighth I/O line GIO<8> to generate the eighth latch data LD<8> when the fourth input pulse signal PIN<4> and the fourth latch control signal LCON<4> are inputted. Each of the second to eighth latch units 332, 333, 334, 335, 336, 337 and 338 may have substantially the same configuration as the first latch unit 331 except I/O signals thereof. Thus, detailed descriptions of the second to eighth latch units 332, 333, 334, 335, 336, 337 and 338 will be omitted hereinafter.

An operation of a data output circuit including the latch unit illustrated in FIG. 7 will be described hereinafter with reference to FIGS. 1, 7 and 8 in conjunction with an example that data loaded on the I/O lines are latched according to the first and second latch control signals LCON<1:2> generated by first and second pulses of the read command signal RD and latch periods of the data are controlled by the third and fourth latch control signals LCON<3:4> generated by third and fourth pulses of the read command signal RD to thus output the first to fourth output data DOUT<1:4>.

First, at a point of time “T11”, the pulse generator 11 of the latch control signal generator 10 may receive a first pulse of the read command signal RD synchronized with the external clock signal CLK to generate the first input pulse signal PIN<1> having a logic “high” level and to generate the first output pulse signal POUT<1> having a logic “high” level.

Next, at a point of time “T12”, the pulse width controller 12 of the latch control signal generator 10 may receive the first output pulse signal POUT<1> having a logic “high” level to generate the first latch control signal LCON<1> having a logic “high” level. The latch unit 31 of the data output portion 30 may receive the first input pulse signal PIN<1> having a logic “high” level to latch the data loaded on the first and second I/O lines GIO<1> and GIO<2> and may receive the first latch control signal LCON<1> having a logic “high” level to generate the first and second latch data LD<1> and LD<2>.

Subsequently, at a point of time “T13”, the selection signal generator 21 of the output control signal generator 20 may receive the first output pulse signal POUT<1> having a logic “high” level to generate the first selection signal SEL<1> having a logic “high” level. The output control signal generator 22 of the output control signal generator 20 may receive the first selection signal SEL<1> having a logic “high” level to generate the first output control signal SOSE<1> having a logic “high” level and the second output control signal SOSE<2> having a logic “low” level. The buffer unit 32 of the data output portion 30 may receive the first output control signal SOSE<1> having a logic “high” level to output the first latch data LD<1> latched at the point of time “T2” as the first output data DOUT<1>. That is, the data output portion 30 may receive the first output control signal SOSE<1> after a level of the first latch data LD<1> is stabilized, thereby stably outputting the first output data DOUT<1>.

Next, at a point of time “T14”, the pulse generator 11 of the latch control signal generator 10 may receive a second pulse of the read command signal RD synchronized with the external clock signal CLK to generate the second input pulse signal PIN<2> having a logic “high” level and to generate the second output pulse signal POUT<2> having a logic “high” level. The output control signal generator 22 of the output control signal generator 20 may receive the first selection signal SEL<1> having a logic “high” level to generate the first output control signal SOSE<1> having a logic “low” level and to generate the second output control signal SOSE<2> having a logic “high” level. The buffer unit 32 of the data output portion 30 may receive the second output control signal SOSE<2> having a logic “high” level to output the second latch data LD<2> latched at the point of time “T12” as the second output data DOUT<2>. That is, the data output portion 30 may receive the second output control signal SOSE<2> after a level of the second latch data LD<2> is stabilized, thereby stably outputting the second output data DOUT<2>.

Next, at a point of time “T15”, the pulse width controller 12 of the latch control signal generator 10 may receive the second output data DOUT<2> having a logic “high” level to generate the second latch control signal LCON<2> having a logic “high” level. The latch unit 31 of the data output portion 30 may receive the second input pulse signal PIN<2> having a logic “high” level to latch the data loaded on the first and second I/O lines GIO<1> and GIO<2> and may receive the second latch control signal LCON<2> having a logic “high” level to generate the third and fourth latch data LD<3> and LD<4>.

Subsequently, at a point of time “T16”, the selection signal generator 21 of the output control signal generator 20 may receive the second output pulse signal POUT<2> having a logic “high” level to generate the second selection signal SEL<2> having a logic “high” level. The output control signal generator 22 of the output control signal generator 20 may receive the second selection signal SEL<2> having a logic “high” level to generate the first output control signal SOSE<1> having a logic “high” level and the second output control signal SOSE<2> having a logic “low” level. The buffer unit 32 of the data output portion 30 may receive the first output control signal SOSE<1> having a logic “high” level to output the third latch data LD<3> latched at the point of time “T15” as the third output data DOUT<3>. That is, the data output portion 30 may receive the first output control signal SOSE<1> after a level of the third latch data LD<3> is stabilized, thereby stably outputting the third output data DOUT<3>.

Next, at a point of time “T17”, the pulse generator 11 of the latch control signal generator 10 may receive a third pulse of the read command signal RD synchronized with the external clock signal CLK to generate the third input pulse signal PIN<3> having a logic “high” level and to generate the third output pulse signal POUT<3> having a logic “high” level. The output control signal generator 22 of the output control signal generator 20 may receive the second selection signal SEL<2> having a logic “high” level to generate the first output control signal SOSE<1> having a logic “low” level and to generate the second output control signal SOSE<2> having a logic “high” level. The buffer unit 32 of the data output portion 30 may receive the second output control signal SOSE<2> having a logic “high” level to output the fourth latch data LD<4> latched at the point of time “T15” as the fourth output data DOUT<4>. That is, the data output portion 30 may receive the second output control signal SOSE<2> after a level of the fourth latch data LD<4> is stabilized, thereby stably outputting the fourth output data DOUT<4>.

Next, at a point of time “T18”, the pulse width controller 12 of the latch control signal generator 10 may receive the third output pulse signal POUT<3> having a logic “high” level to generate the third latch control signal LCON<3> having a logic “high” level. The latch unit 31 of the data output portion 30 may not generate the first and second latch data LD<1> and LD<2> because the third latch control signal LCON<3> may a logic “high” level.

Next, at a point of time “T19”, the pulse generator 11 of the latch control signal generator 10 may receive a fourth pulse of the read command signal RD synchronized with the external clock signal CLK to generate the fourth input pulse signal PIN<4> having a logic “high” level and to generate the fourth output pulse signal POUT<4> having a logic “high” level.

Subsequently, at a point of time “T20”, the pulse width controller 12 of the latch control signal generator 10 may receive the fourth output pulse signal POUT<4> having a logic “high” level to generate the fourth latch control signal LCON<4> having a logic “high” level. The latch unit 31 of the data output portion 30 may not generate the third and fourth latch data LD<3> and LD<4> because the fourth latch control signal LCON<4> may have a logic “high” level. An operation of the data output circuit for generating the fifth to eighth output data DOUT<5:8> may be substantially the same as the operation of the data output circuit for generating the first to fourth output data DOUT<1:4>. Thus, the operation of the data output circuit for generating the fifth to eighth output data DOUT<5:8> will be omitted hereinafter.

As described above, a data output circuit according to an embodiment of the present invention may increase a pulse width of a latch control signal generated by a read command signal to increase a latch period of data. Furthermore, the data output circuit may generate output control signals during a pulse width period of the latch control signal to output latched data as output data after levels of the latched data are stabilized. Thus, the output data may be stably outputted.

The embodiments of the present invention have been disclosed above for illustrative purposes. Those skilled in the art will appreciate that various modifications, additions and substitutions are possible, without departing from the scope and spirit of the inventive concept as disclosed in the accompanying claims.

What is claimed is:

1. A data output circuit comprising:
a latch control signal generator configured to generate an input pulse signal and a latch control signal, the latch control signal including a pulse whose width is controlled to have a predetermined time period; and
a data output portion configured to latch a data loaded on an input/output (I/O) line during a pulse width period of the latch control signal to generate a latch data and configured to buffer the latch data according to an output control signal generated from a read command signal to output the buffered latch data as an output data.

2. The data output circuit of claim 1, wherein a pulse width of the latch data is equal to that of the latch control signal.

3. The data output circuit of claim 1, wherein a pulse width of the output control signal is less than that of the latch control signal.

4. The data output circuit of claim 1, wherein the latch control signal generator includes:
a pulse generator configured to generate the input pulse signal and an output pulse signal which are enabled at a point of time that the read command signal is inputted; and
a pulse width controller configured to extend a pulse width of the output pulse signal by a predetermined period to generate the latch control signal.

5. The data output circuit of claim 4, wherein the pulse width controller includes:
a first delay unit configured to retard the output pulse signal by half a cycle of an external clock signal to output the retarded output pulse signal through a first node;
a second delay unit configured to retard a signal of the first node by half a cycle of the external clock signal to output the retarded signal through a second node; and
a logic unit configured to generate the latch control signal which is enabled at a point of time that a pulse of the output pulse signal is inputted and which is disabled when a signal of the second node is disabled.

6. The data output circuit of claim 1, wherein the data output portion includes:
a latch unit configured to latch the data loaded on the I/O line during the pulse width period of the latch control signal in response to the input pulse signal to generate the latch data; and
a buffer unit configured to buffer the latch data in response to the output control signal to output the buffered latch data as the output data.

7. A data output circuit comprising:
a latch control signal generator configured to generate a first input pulse signal and a first latch control signal in response to a first pulse of a read command signal and a second input pulse signal and a second latch control signal in response to a second pulse of the read command signal; and
a latch unit configured to latch first and second data loaded on first and second I/O lines during a pulse width period of the first latch control signal to generate first and second latch data and configured to latch third and fourth data loaded on third and fourth I/O lines during a pulse width period of the second latch control signal to generate third and fourth latch data,
wherein the first latch control signal is enabled from when the first pulse of the read command signal is inputted till when a third pulse of the read command signal is inputted, and the second latch control signal is enabled from when the second pulse of the read command signal is inputted till when a fourth pulse of the read command signal is inputted.

8. The data output circuit of claim 7,
wherein a pulse width of the first and second latch data is equal to that of the first latch control signal; and
wherein a pulse width of the third and fourth latch data is equal to that of the second latch control signal.

9. The data output circuit of claim 7, further comprising a buffer unit configured to sequentially output the first and second latch data as a first output data and a second output data in response to a first output control signal and a second output control signal and configured to sequentially output the third and fourth latch data as a third output data and a fourth output data in response to the first and second output control signals.

10. The data output circuit of claim 9, wherein the first and second output control signals are generated during the pulse width period of the first latch control signal or during the pulse width period of the second latch control signal.

11. The data output circuit of claim 9, wherein the first and second output control signals are sequentially generated when the first pulse or the second pulse of the read command signal is inputted.

12. The data output circuit of claim 7, wherein the latch control signal generator includes:
a pulse generator configured to generate the first and second input pulse signals and first and second output pulse signals which are enabled at moments that the first and second pulses of the read command signal are inputted; and
a pulse width controller configured to extend pulse widths of the first and second output pulse signals by a predetermined period to generate the first and second latch control signals.

13. The data output circuit of claim 12, wherein the pulse width controller includes:
a first pulse width controller configured to extend a pulse width of the first output pulse signal by one cycle of an external clock signal to generate the first latch control signal; and
a second pulse width controller configured to extend a pulse width of the second output pulse signal by one cycle of the external clock signal to generate the second latch control signal.

14. The data output circuit of claim 13, wherein the first pulse width controller includes:
a first delay unit configured to retard the first output pulse signal by half a cycle of the external clock signal to output the retarded first output pulse signal through a first node;
a second delay unit configured to retard a signal of the first node by half a cycle of the external clock signal to output the retarded second signal through a second node; and
a logic unit configured to generate the first latch control signal which is enabled at a point of time that a pulse of the first output pulse signal is inputted and which is disabled when a signal of the second node is disabled.

15. The data output circuit of claim 14, wherein the second pulse width controller includes:
a third delay unit configured to retard the second output pulse signal by half a cycle of the external clock signal to output the retarded third output pulse signal through a third node;
a fourth delay unit configured to retard a signal of the third node by half a cycle of the external clock signal to output the retarded signal through a fourth node; and
a logic unit configured to generate the second latch control signal which is enabled at a point of time that a pulse of the second output pulse signal is inputted and which is disabled when a signal of the fourth node is disabled.

16. The data output circuit of claim 11, further comprising an output control signal generator configured to generate the first and second output control signals which are sequentially enabled when the first or second output pulse signals is inputted.

17. The data output circuit of claim 16, wherein the first and second output control signals are enabled during the pulse width periods of the first and second latch control signals.

18. The data output circuit of claim 16, wherein periods for latching the first to fourth data to generate the first to fourth latch data are set to a pulse width of the first and second latch control signals.

19. A data output circuit comprising:
a latch control signal generator configured to generate an input pulse signal, an output pulse signal and a latch control signal, the latch control signal including a pulse whose width is controlled to have a predetermined time period;
an output control signal generator configured to generate first and second output control signals enabled when the output pulse signal is inputted; and
a data output portion configured to latch first and second data loaded on first and second input/output (I/O) lines during a pulse width period of the latch control signal to generate first and second latch data and buffer the first and second latch data according to the first and second output control signals to output the buffered first and second latch data as a first output data and a second output data.

20. The data output circuit of claim 19,
wherein a pulse width of the first and second latch data is equal to that of the latch control signal; and
wherein the first and second output control signals are enabled during the pulse width period of the latch control signal.

21. A data output circuit comprising:
a latch control signal generator configured to generate one or more input pulse signals and one or more latch control signals having a predetermined pulse width; and
a data output portion configured to latch data loaded onto a one or more input/output lines to generate a plurality of latch data and buffer the plurality of latch data to output a plurality of output data.

22. The data output circuit of claim 21, further comprising:
a selection signal generator configured to generate a first selection signal and a second selection signal when one or more output pulse signals are inputted.

23. The data output circuit of claim 22, further comprising:
an output control signal generator configured to generate a first output control signal and a second output control signal when the first selection signal or the second selection signal are inputted.

24. The data output circuit of claim 22, further comprising:
a pulse width controller configured to control pulse widths of the one or more output pulse signals to generate the one or more latch control signals having the predetermined pulse width.

25. The data output circuit of claim 24, wherein the pulse width controller comprises:
a first delay unit configured to retard the first output signal and output the retarded first output signal;
a second delay unit configured to retard a signal of a node to output the signal through another node; and
a logic unit configured to generate the one or more latch control signals.
